(19) United States
(12) Patent Application Publication
(10) Pub. No.: US 2009/0032961 A1
(43) Pub. Date: Feb. 5, 2009

(54) SEMICONDUCTOR DEVICE HAVING A LOCALLY ENHANCED ELECTROMIGRATION RESISTANCE IN AN INTERCONNECT STRUCTURE

(76) Inventors: Frank Feustel, Dresden (DE); Tobias Letz, Dresden (DE); Thomas Werner, Moritzburg (DE)

Correspondence Address: WILLIAMS, MORGAN & AMERSON, 10333 RICHMOND, SUITE 1100, HOUSTON, TX, 77042, US

(21) Appl. No.: 12/036,362

(22) Filed: Feb. 25, 2008

(30) Foreign Application Priority Data
Jul. 31, 2007 (DE) 10 2007 035 834.4

(51) Int. Cl. H01L 21/768; H01L 23/538

(52) U.S. Cl. 257/773; 438/637; 257/E21.585; 257/E23.169

(57) ABSTRACT

By forming an alloy in a highly localized manner at a transition or contact area between a via and a metal line, the probability of forming an electromigration-induced shallow void may be significantly reduced, while not unduly affecting the overall electrical resistivity of the metal line. In one illustrative embodiment, an electroless deposition process may provide the alloy-forming species on the exposed metal region on the basis of an electroless plating process.

### BACKGROUND OF THE INVENTION

1. Field of the Invention

Generally, the present disclosure relates to the formation of microstructures, such as advanced integrated circuits, and, more particularly, to the formation of conductive structures, such as copper-based metallization layers, and techniques to reduce electromigration and other stress-induced mass transport effects during operation.

2. Description of the Related Art

In the field of fabricating modern microstructures, such as integrated circuits, there is a continuous drive to steadily reduce the feature sizes of microstructure elements, thereby enhancing the functionality of these structures. For instance, in modern integrated circuits, minimum feature sizes, such as the channel length of field effect transistors, have reached the deep sub-micron range, thereby increasing performance of these circuits in terms of speed and/or power consumption. As the size of individual circuit elements is reduced with every new circuit generation, thereby improving, for example, the switching speed of the transistor elements, the available floor space for interconnect lines electrically connecting the individual circuit elements is also decreased. Consequently, the dimensions of these interconnect lines are also reduced to compensate for a reduced amount of available floor space and for an increased number of circuit elements provided per unit die area, as typically the number of interconnections required increases over-proportionally relative to the number of circuit elements. Thus, usually a plurality of stacked “wiring” layers, also referred to as metallization layers, is provided, wherein individual metal lines of one metallization layer are connected to individual metal lines of an overlying or underlying metallization layer by so-called vias. Despite the provision of a plurality of metallization layers, reduced dimensions of the interconnect lines are necessary to comply with the enormous complexity of, for instance, modern CPUs, memory chips, ASICs (application specific ICs) and the like. The reduced cross-sectional area of the interconnect structures, possibly in combination with an increase of the static power consumption of extremely scaled transistor elements, may result in considerable current densities in the metal lines, which may even increase with every new device generation.

Advanced integrated circuits, including transistor elements having a critical dimension of 0.1 μm and even less, may, therefore, typically be operated at significantly increased current densities of up to several kA per cm² in the individual interconnect structures, despite the provision of a relatively large number of metallization layers, owing to the significant number of circuit elements per unit area. Operating the interconnect structures at elevated current densities, however, may entail a plurality of problems related to stress-induced line degradation, which may finally lead to premature failure of the integrated circuit. One prominent phenomenon in this respect is the current-induced mass transport in metal lines and vias, also referred to as “electromigration.” Electromigration is caused by momentum transfer of electrons to the ion cores in the conductors, resulting in a net momentum in the direction of electron flow. In particular, at high current densities, a significant collective motion or directed diffusion of atoms may be caused due to electromigration in the interconnect metal, wherein the presence of respective diffusion paths may have a substantial influence on the displaced amount of mass resulting from the momentum transfer. Thus, electromigration may lead to the formation of voids within and hillocks next to the metal interconnect, thereby resulting in reduced performance and reliability or complete failure of the device. For instance, aluminum lines embedded into silicon dioxide and/or silicon nitride are frequently used as metal for metallization layers, wherein, as explained above, advanced integrated circuits having critical dimensions of 0.1 μm or less, may require significantly reduced cross-sectional areas of the metal lines and, thus, increased current densities, which may render aluminum less attractive for the formation of metallization layers.

Consequently, aluminum is being replaced by copper and copper alloys, a material with significantly lower resistivity and improved resistance to electromigration even at considerably higher current densities compared to aluminum. The introduction of copper into the fabrication of microstructures and integrated circuits comes along with a plurality of severe problems residing in copper's characteristic to readily diffuse in silicon dioxide and a plurality of low-k dielectric materials, which are typically used in combination with copper in order to reduce the parasitic capacitance within complex metallization layers. In order to provide the necessary adhesion and to avoid the undesired diffusion of copper atoms into sensitive device regions, it is, therefore, usually necessary to provide a barrier layer between the copper and the dielectric material in which the copper-based interconnect structures are embedded. Although silicon nitride is a dielectric material that effectively prevents the diffusion of copper atoms, selecting silicon nitride as an interlayer dielectric material may be less than desirable, since silicon nitride exhibits a moderately high permittivity, thereby increasing the parasitic capacitance of neighboring copper lines, which may result in non-tolerable signal propagation delays. Hence, a thin conductive barrier layer that also imparts the required mechanical stability to the copper is usually formed so as to separate the bulk copper from the surrounding dielectric material, thereby reducing copper diffusion into the dielectric materials and also reducing the diffusion of unwanted species, such as oxygen, fluorine and the like, into the copper. Furthermore, the conductive barrier layers may also provide highly stable interfaces with the copper, thereby reducing the probability for significant mass transport at these interfaces, which are typically a critical region in view of increased diffusion paths. Currently, tantalum, titanium, tungsten and their compounds with nitrogen and silicon and the like, are preferred candidates for a conductive barrier layer, wherein the barrier layer may comprise two or more sub-layers of different composition so as to meet the requirements in terms of diffusion suppressing and adhesion properties.

Another characteristic of copper significantly distinguishing it from aluminum is the fact that copper may not be readily deposited in larger amounts by chemical and physical vapor deposition techniques, in addition to the fact that copper may not be efficiently patterned by anisotropic dry etch processes, thereby requiring a process strategy that is commonly referred to as the damascene or inlaid technique. In the damascene process, first a dielectric layer is formed which is then patterned to include trenches and/or vias which are subsequently filled with copper, wherein, as previously noted, prior to filling in the copper, a conductive barrier layer is formed on sidewalls of the trenches and vias. The deposition of the bulk copper material into the trenches and vias is usually accomplished by wet chemical deposition processes, such as electroplating and electroless plating, thereby requiring the reliable filling of vias with an aspect ratio of 5 and more with a diameter of 0.3 μm or even less in combination with trenches having a width ranging from 0.1 μm to several μm. Electrochemical deposition processes for copper are well established in the field of electronic circuit board fabrication. However, the void-free filling of high aspect ratio vias is an extremely complex and challenging task, wherein the characteristics of the finally obtained copper-based interconnect structure significantly depend on process parameters, materials and geometry of the structure of interest. Since the geometry of interconnect structures is substantially determined by the design requirements and may, therefore, not be significantly altered for a given microstructure, it is of great importance to estimate and control the impact of materials, such as conductive and non-conductive barrier layers, of the copper microstructure and their mutual interaction on the characteristics of the interconnect structure so as to insure both high yield and the required product reliability. In particular, it is important to identify, monitor and reduce degradation and failure mechanisms in interconnect structures for various configurations so as to maintain device reliability for every new device generation or technology node.

Accordingly, a great deal of effort has been made in investigating the degradation of copper interconnects, especially in combination with low-k dielectric materials having a relative permittivity of 3.1 or even less, in order to find new materials and process strategies for forming copper-based lines and vias with a low overall permittivity. Although the exact mechanism of electromigration in copper lines is still not quite fully understood, it turns out that voids positioned in and on sidewalls and especially at interfaces to neighboring materials may have a significant impact on the finally achieved performance and reliability of the interconnects.

One prominent failure mechanism which is believed to significantly contribute to a premature device failure is the electromigration-induced material transport, particularly at transition areas between a via and a metal region, wherein usually a certain amount of conductive barrier material may be provided at the bottom of the via, thereby representing a barrier for the material flow, as will be described in more detail with reference to FIG. 1a.

FIG. 1a schematically illustrates a cross-sectional view of a semiconductor device 100 comprising a substrate 101 that may represent any appropriate carrier material for forming thereon and therein circuit elements, such as transistors and the like. For example, the substrate 101 may represent a bulk silicon substrate, a silicon-on-insulator (SOI) substrate and the like. A device layer 102 may be formed above the substrate 101 and may include a plurality of semiconductor elements wherein, for convenience, any such circuit elements are not shown in FIG. 1a. Furthermore, the semiconductor device 100 comprises a first metallization layer 110, which may comprise a dielectric material 111 and a metal line 112, which is typically comprised of highly conductive metal, such as copper, in advanced applications. Moreover, the metal line 112 may comprise a conductive barrier layer 113, which may be comprised of tantalum, tantalum nitride and the like, in order to provide the required adhesion and diffusion blocking characteristics, as previously explained. A second metallization layer 120 may be provided above the first metallization layer 110 and may also comprise a dielectric material 121 and a metal line 122 formed therein, wherein the dielectric material 121 and the conductive material of the line 122 may be comprised of substantially the same materials as may also be used in the first metallization layer 110. Thus, a dominant part of the conductive material in the metal line 122 may be copper, while typically low-k dielectric materials are used for the dielectric materials 121 and 111. Furthermore, the metal lines 112 and 122 are electrically connected by a via 130 which may have a diameter or lateral dimensions in lower metallization levels of the device 100 in the range of 100 nm and less. Furthermore, a conductive barrier layer 123 may cover the sidewalls and the bottom areas of the metal line 122 and the via 130.

The semiconductor device 100 as shown in FIG. 1a may, according to well-established conventional process strategies, be formed on the basis of the following processes. After manufacturing respective circuit elements in the device layer 102, the metallization layer 110 may be formed by depositing the dielectric material 111 and patterning appropriate trenches and other openings on the basis of sophisticated lithography and etch techniques. Thereafter, the barrier layer 113 may be formed, for instance, on the basis of sputter deposition, chemical vapor deposition (CVD) and the like. Next, a seed layer, for instance comprised of copper, may be deposited if required, followed by an electrochemical deposition process, such as electroplating, in order to fill the previously patterned openings, wherein any excess material created during the electrochemical deposition may be removed afterwards, for instance, by chemical mechanical polishing (CMP) and/or etching. Thereafter, depending on the process strategy, an etch stop layer 124 may be deposited, which may also act as a cap layer for the metal line 112, thereby confining the copper material and providing the desired inertness of the metal line 112. As previously explained, the material composition of the etch stop layer 124 may also be selected with respect to electromigration performance in order to reduce any diffusion paths within the metal line 112.

Next, the dielectric material 121 may be formed on the basis of any appropriate process and thereafter respective openings may be patterned for the via and the metal line 122. In well-established techniques, so-called dual damascene techniques, the opening for the via 130 may be formed first on the basis of an anisotropic etch process which may be reliably controlled on the basis of the etch stop layer 124. Thereafter, the trench opening may be patterned wherein, in some approaches, the respective via opening may be completely opened so as to connect to the metal line 111. Next, an appropriate clean process, if required, may be performed and thereafter the barrier layer 123 may be deposited on the basis of any appropriate deposition technique. Next, the conductive material, i.e., the copper, may be filled in on the basis of an electrochemical deposition process, which may be preceded by the deposition of a seed layer. Thereafter, the resulting surface topography may be planarized, thereby also removing any excess material and a further etch stop layer or cap layer 125 may be formed on the basis of CVD and the like.

During operation of the semiconductor device 100, an electron flow may be established as, for instance, indicated by arrow 126, which may result in a material flow due to the increased current densities typically encountered in advanced semiconductor devices, as previously explained. As shown, a certain amount of barrier material may be present at the bottom of the via 130, which may exhibit a high resistance against electromigration compared to substantially pure copper, and thus significant material flow from the via 130 into the metal line 112 may be prevented. It turns out, however, that the transition area 131 between the metal line 112 and the via 130 may suffer from increased material depletion since new material may not be “delivered” by the via 130. Consequently, a shallow void 131A may form in the transition area 131, which may finally result in a contact failure which may result in a total loss of the device 100.

In order to reduce the effect of the above-described failure mechanism, it has been proposed to strengthen the upper portion of the metal line 112 by providing, for instance, an appropriate metal, such as a compound comprised of cobalt/tungsten/phosphorous, or by forming an alloy in the upper part of the metal line 112, as many alloys have proven to exhibit a higher resistance against electromigration compared to relatively poor copper.

FIG. 1b schematically illustrates the semiconductor device 100 when comprising a conductive cap layer 112A, which may be formed of an alloy such as a tin/copper alloy, an aluminum/copper alloy and the like. In other cases, a conductive material, such as a compound identified above, may be used for the layer 112A. The layer 112A may typically be formed after the electrochemical deposition of the bulk material of the metal line 112 and after a corresponding planarization and removal of excess material. It turns out that, although a significant improvement in reliability of the semiconductor device 100 may be achieved, due to the enhanced resistance against electromigration effects at the transition area 131, an overall degradation of electrical performance may be observed, which may be attributed to an increased series resistance of the metal line 112 due to the presence of the layer 112A, which may typically have a significantly higher electrical resistivity compared to the bulk material of the metal line 112.

The present disclosure is directed to various methods and devices that may avoid, or at least reduce, the effects of one or more of the problems identified above.

### SUMMARY OF THE INVENTION

The following presents a simplified summary of the invention in order to provide a basic understanding of some aspects of the invention. This summary is not an exhaustive overview of the invention. It is not intended to identify key or critical elements of the invention or to delineate the scope of the invention. Its sole purpose is to present some concepts in a simplified form as a prelude to the more detailed description that is discussed later.

Generally, the subject matter disclosed herein relates to semiconductor devices and corresponding manufacturing techniques, wherein an enhanced electrical performance of metallization structures may be achieved, while nevertheless an increased resistance against electromigration is obtained, in particular at transition areas connecting a via and a lower lying metal line. An enhanced electromigration performance may be obtained by locally forming an alloy in an area of the metal region in which the via terminates. Consequently, the transition area may substantially no longer act as a material source during operation of the device, thereby significantly reducing the probability of creating shallow voids therein. Moreover, since the alloy providing enhanced electromigration performance may only be locally provided in the transition area, the overall resistance of the corresponding metal region is affected in a highly localized manner, only wherein the major portion of the metal region may further exhibit a moderately desired low series resistance. In some illustrative aspects, the alloy may be provided in a highly self-aligned manner, thereby ensuring a high degree of electromigration reliability while not consuming undue material portions of the highly conductive material of the metal line under consideration.

One illustrative method disclosed herein comprises forming an opening in a dielectric layer that is formed above a metal-containing region of a metallization structure of a semi-conductor device. The method further comprises applying an alloy-forming species through the opening so as to bring the alloy-forming species in contact with material of the metal-containing region. Thereafter, an alloy is formed in the metal-containing region so as to connect to the opening and additionally the opening is filled with a metal-containing material.

Another illustrative method disclosed herein relates to forming an interconnect structure of a semiconductor device wherein the method comprises providing an alignment opening in a layer stack formed above a metal line, wherein the alignment opening is to be used for forming a via connecting to the metal line. Furthermore, the method comprises locally forming an alloy in a portion of the metal line using the alignment opening to align the portion to the via.

One illustrative semiconductor device disclosed herein comprises a first metallization layer comprising a first metal region, wherein the first metal region comprises an alloy that is laterally substantially restricted to a contact region. The semiconductor device further comprises a second metallization layer formed above the first metallization layer and comprising a second metal region. Additionally, an interconnect structure connecting the first and second metal regions is provided, wherein one end of the interconnect structure terminates in the contact region.

### BRIEF DESCRIPTION OF THE DRAWINGS

The disclosure may be understood by reference to the following description taken in conjunction with the accompanying drawings, in which like reference numerals identify like elements, and in which:

FIGS. 1a-1b schematically illustrate cross-sectional views of a conventional semiconductor device including a metallization structure with inferior electromigration performance with respect to a contact region or transition region located below a via connecting to a metal line (FIG. 1a) and with inferior electrical performance due to increased series resistance of a metal line (FIG. 1b);

FIGS. 2a-2f schematically illustrate cross-sectional views of a semiconductor device during various manufacturing stages in forming an interconnect structure for connecting two adjacent metallization levels based on a local alloy formed in a contact or transition area wherein an alloy-forming species may be deposited on the basis of highly selective deposition techniques according to illustrative embodiments;

FIGS. 3a-3b schematically illustrate cross-sectional views of a semiconductor device during relevant manufacturing phases for forming a locally restricted material composition for enhancing the electromigration performance on the basis of particle bombardment according to further illustrative embodiments; and

FIGS. 3c-3d schematically illustrate cross-sectional views of a semiconductor device during relevant manufacturing stages for forming an alloy in a highly localized manner on the basis of an implantation process according to still further illustrative embodiments.

While the subject matter disclosed herein is susceptible to various modifications and alternative forms, specific embodiments thereof have been shown by way of example in the drawings and are herein described in detail. It should be understood, however, that the description herein of specific embodiments is not intended to limit the invention to the particular forms disclosed, but on the contrary, the intention is to cover all modifications, equivalents, and alternatives falling within the spirit and scope of the invention as defined by the appended claims.

### DETAILED DESCRIPTION

Various illustrative embodiments of the invention are described below. In the interest of clarity, not all features of an actual implementation are described in this specification. It will of course be appreciated that in the development of any such actual embodiment, numerous implementation-specific decisions must be made to achieve the developers' specific goals, such as compliance with system-related and business-related constraints, which will vary from one implementation to another. Moreover, it will be appreciated that such a development effort might be complex and time-consuming, but would nevertheless be a routine undertaking for those of ordinary skill in the art having the benefit of this disclosure.

The present subject matter will now be described with reference to the attached figures. Various structures, systems and devices are schematically depicted in the drawings for purposes of explanation only and so as to not obscure the present disclosure with details that are well known to those skilled in the art. Nevertheless, the attached drawings are included to describe and explain illustrative examples of the present disclosure. The words and phrases used herein should be understood and interpreted to have a meaning consistent with the understanding of those words and phrases by those skilled in the relevant art. No special definition of a term or phrase, i.e., a definition that is different from the ordinary and customary meaning as understood by those skilled in the art, is intended to be implied by consistent usage of the term or phrase herein. To the extent that a term or phrase is intended to have a special meaning, i.e., a meaning other than that understood by skilled artisans, such a special definition will be expressly set forth in the specification in a definitional manner that directly and unequivocally provides the special definition for the term or phrase.

The subject matter of the present disclosure is directed to semiconductor devices and associated manufacturing techniques in which a material may be introduced into a metal region in a highly laterally restricted manner in order to enhance the electromigration performance of the laterally restricted area. For this purpose, an alloy-forming species may be brought into contact with the bulk material of the metal region such that a self-aligned behavior with respect to a corresponding via may be achieved. In this respect, an alloy is to be understood as a material mixture exhibiting a metallic characteristic that is comprised of two or more components, at least one of which is a metal. A laterally restricted region of a metal alloy may further be understood as a region having, at least in one lateral dimension, for instance along a length direction of a metal line, a significantly reduced size compared to the metal line, wherein it should be appreciated that the alloy may not necessarily form a sharp boundary between the non-alloyed area and the alloyed area in the metal region. Nevertheless, a non-alloyed region with respect to a specific alloy-forming species may be distinguished from an alloyed region, for instance on the basis of the concentration of the alloy-forming species, by defining an appropriate threshold. For example, a point of maximum concentration of the alloy-forming species under consideration may be determined and a neighborhood of this point may be considered an alloyed region, as long as the concentration of the alloy-forming species under consideration is higher than a specified percentage of the maximum concentration.

As previously explained, copper alloys may per se exhibit a higher electromigration performance compared to moderately poor copper, however, at the cost of increased electrical resistivity. Thus, by providing the alloy in a highly laterally restrictive manner based on an appropriate alignment mechanism, the alloy may be provided at those areas where a significant resistance against electromigration is required, while not unduly negatively affecting the electrical performance of the remaining portion of the metal line under consideration. A substantially self-aligned manufacturing technique may be established by appropriately “coupling” manufacturing processes used to form a via opening with appropriate process techniques for incorporating the desired alloy-forming material into a portion of the underlying metal line. In some illustrative aspects disclosed herein, a highly selective deposition technique on the basis of electrochemical processes may be used at an appropriate manufacturing stage when the via opening exposes the underlying metal line. Consequently, a desired material may be efficiently deposited on the exposed surface and may be subsequently thermally driven into the metal area, thereby forming the desired alloy. In other cases, highly non-conformal deposition techniques may be used to appropriately form a desired alloy-forming material on the exposed surface portion of the metal line. In still other illustrative embodiments disclosed herein, other process techniques, including a highly directive particle bombardment, may be used to incorporate a desired alloy-forming species in a self-aligned fashion.

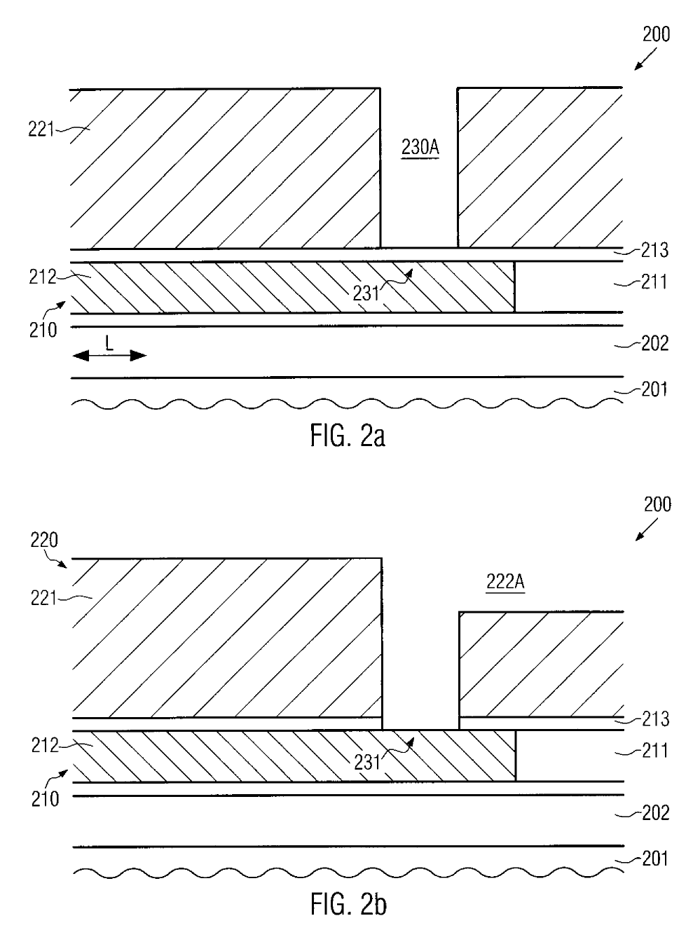

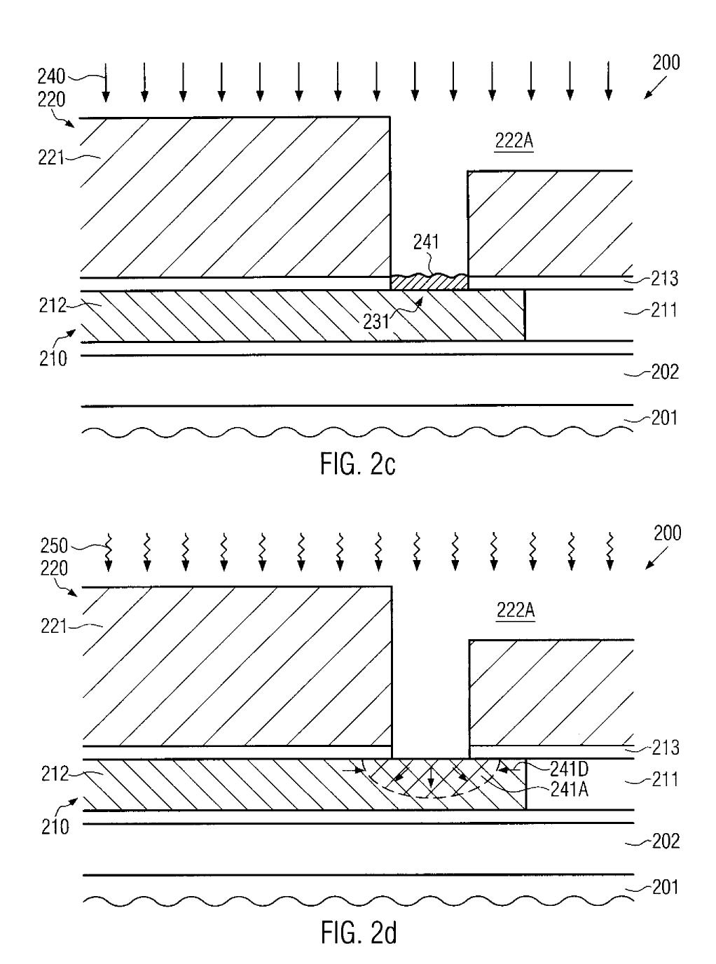

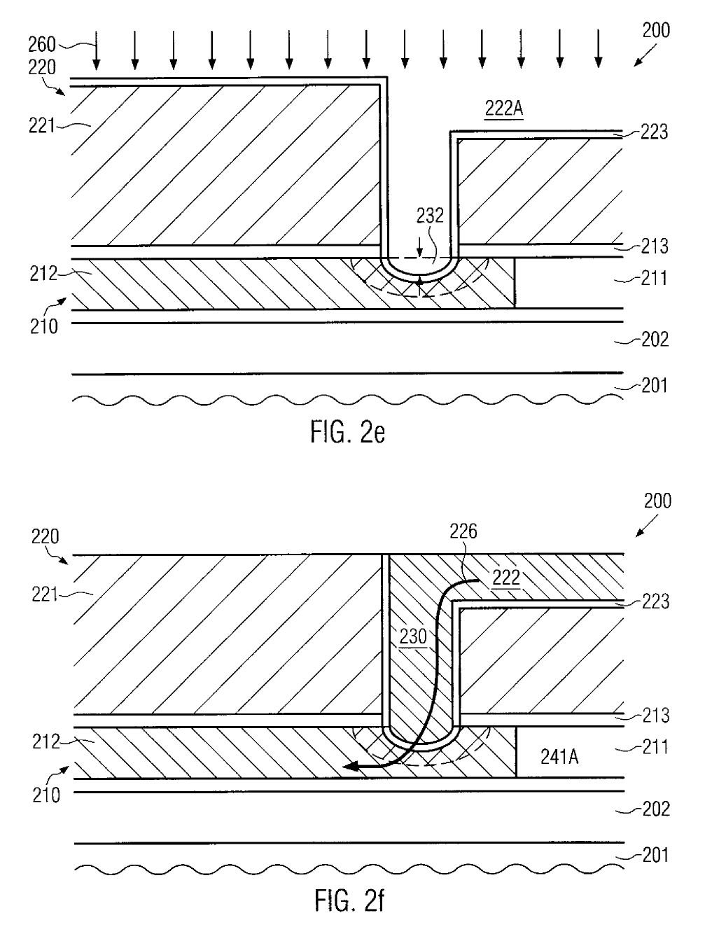

FIG. 2a schematically illustrates a cross-sectional view of a semiconductor device 200 in an advanced manufacturing stage in which a metallization structure is to be formed. The semiconductor device 200 may comprise a substrate 201, which may represent any appropriate carrier material, such as semiconductive materials, insulating materials and the like. For example, the substrate 201 may represent a substantially crystalline semiconductor material, such as silicon, germanium, a semiconductor compound and the like. In other cases, the substrate 201 may comprise, at least partially, an insulating layer above which an appropriate material in the form of a device layer 202 may be provided, which is suitable for forming therein and thereon microstructure features, which may at least contain some circuit elements requiring an electrical interconnection on the basis of a respective metallization structure. Thus, unless otherwise stated in the specification and/or the appended claims, the subject matter disclosed herein should not be considered as being restricted to any specific semiconductor material and carrier material for the substrate 201 and the device layer 202.

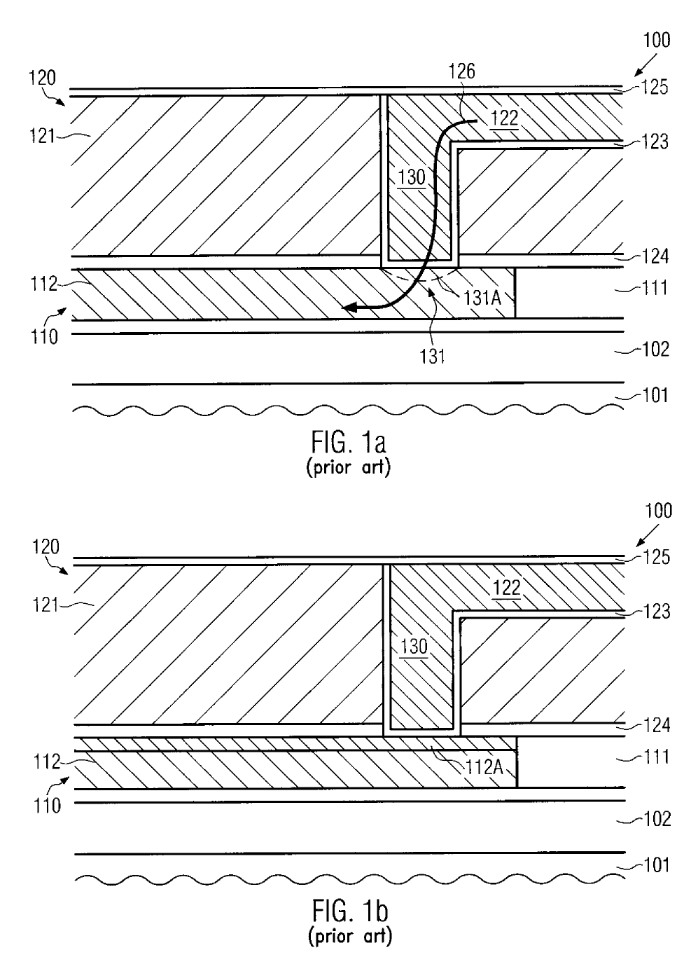

Furthermore, a first metallization layer 210 may be provided, which may not necessarily represent the very first metallization layer formed above the device layer 202 but may represent any intermediate layer, depending on the device requirements. For example, certain metallization levels may exhibit a less pronounced inferior performance with respect to electromigration, while other metallization levels may exhibit inferior electromigration performance or electrical performance, as previously explained with reference to FIGS. 1a-1b. The metallization layer 210 may comprise a dielectric material 211, which may be comprised of any appropriate material or material compositions as required. For instance, the dielectric material 211 may comprise a low-k dielectric material, i.e., a material having a relative permittivity of 3.0 or less, in order to reduce parasitic capacitances, as previously explained. Furthermore, a metal region 212 may be provided in the dielectric material, wherein the metal region 212 may be substantially comprised of a highly conductive metal, such as copper, silver, alloys thereof and the like. It should be appreciated that the metal region 212 may also comprise a conductive material of lower conductivity at interfaces to the surrounding dielectric material 211. A corresponding less conductive material may also be referred to as a barrier layer, as is also previously described when referring to the device 100, wherein a corresponding barrier material typically comprises moderately sharp boundaries with respect to the highly conductive material so that even a corresponding interface between the barrier material and the highly conductive material may not be considered as an alloy region. As previously explained, appropriate barrier materials in a copper-based metallization regime are tantalum, tantalum nitride, titanium, titanium nitride, a plurality of compounds such as cobalt, tungsten, phosphorous or a compound of cobalt, tungsten, boron, compounds of nickel, molybdenum, boron, and the like.

Furthermore, the metallization layer 210 may comprise a cap layer 213 which may reliably confine the material of the metal region 212 with respect to diffusion in an overlying dielectric material 221 that may be provided for forming a further metallization level and an appropriate interconnect structure of via for providing an interlevel connection. As previously explained, the layer 213 may also act as an etch stop layer during the patterning of the dielectric material 221. For example, silicon nitride, silicon carbide, nitrogen-enriched silicon carbide, or any compositions thereof, and the like, may be efficiently used for the layer 213. The dielectric layer 221 formed above the metallization layer 210 may, in this manufacturing stage, comprise a via opening 230 that may extend through the dielectric material 211 and may terminate on or in the layer 213.

The semiconductor device 200 as shown in FIG. 2a may be formed on the basis of well-established process techniques which may be similar to the processes previously described with reference to the semiconductor device 100. That is, circuit elements, possibly in combination with other microstructural features, may be formed in the device layer 202, wherein transistor elements may be formed having critical dimensions on the order of magnitude of 50 nm and less, as are typically used in sophisticated integrated circuits, such as CPUs and the like. Thereafter, an appropriate contact structure may be formed to provide electrical connection to respective conductive semiconductor areas of the circuit element in the device layer 202. Next, one or more metallization levels may be provided when the metallization layer 210 does not represent the very first metallization layer. Thereafter the dielectric material 211 may be formed on the basis of any appropriate deposition technique, wherein it should be appreciated that well-established material compositions, for instance including etch stop layers and the like, may be incorporated in the material 211. Subsequently, well-established patterning regimes may be used to form openings corresponding to the metal region 212, which is typically provided in the form of a metal line which may have a lateral extension in one dimension, referred to as length direction and indicated as L in FIG. 2a, that may be significantly greater compared to a lateral width direction, which is to be understood as a direction perpendicular to the drawing plane of FIG. 2a. For instance, a corresponding line width may be approximately 100 nm and less for narrow metal lines, and may range up to several micrometers for wide metal lines, whereas the extension in the length direction may be several micrometers up to several tenths of micrometers.

As previously explained, a highly conductive material, such as copper, may be used for forming the metal region 212, wherein typically an appropriate barrier material may be provided, as previously explained. After forming the metal region 212, the cap layer 213 may be deposited on the basis of process techniques as also explained with reference to the semiconductor device 100. It should be appreciated that the metal region 212 and the cap layer 213 may be formed on the basis of process and device requirements selected such that a desired electrical, mechanical and thermal performance is obtained. That is, contrary to conventional approaches, any global treatment of the metal region 212 with respect to enhancing the electromigration behavior in view of the creation of shallow voids at a contact area or transition area on and in which a respective via is to be received, may be omitted since the subject matter disclosed herein may provide highly local enhancement of the electromigration behavior in the contact region 231. In particular, any resistivity increasing measures for globally enhancing the electromigration behavior of the upper portion of the metal region 212 may not be necessary.

The dielectric material 221 may be formed on the basis of any appropriate deposition technique and may thereafter be patterned by well-established patterning regimes, including a photolithography process and a subsequent anisotropic etch sequence on the basis of well-established recipes. In one illustrative embodiment, the dielectric material 221 may represent the dielectric material of a further metallization layer including an intermediate layer for providing a respective via on the basis of the opening 230 so that the initial height of the dielectric material 221 represents the depth of a respective metal line still to be formed plus the depth of a respective via. It should be appreciated, however, that the principles disclosed herein may be efficiently applied to other approaches, for instance to techniques in which respective vias are formed independently from respective metal lines of a subsequent metallization layer. In other cases, a trench opening may be formed first and thereafter the via opening 230A may be formed within the trench opening, which may also be referred to as a “trench first, via last” approach. During the corresponding anisotropic etch sequence for forming the via opening 230A, the layer 213 may be efficiently used as an etch stop, thereby avoiding an undue exposure of the material of the region 212, when a subsequent trench patterning sequence is to be performed. In other cases, the etch stop layer 213 may be opened during an etch sequence for forming the opening 230A according to a single damascene strategy or in accordance with the above-specified “trench first, via last” approach.

FIG. 2b schematically illustrates the semiconductor device 200 in a further advanced manufacturing stage, wherein a trench opening 222A is formed in the dielectric material 221, thereby defining a second metallization layer 220, which may be electrically connected to the metallization layer 210 by means of a via to be formed on the basis of a via opening 230A. The trench opening 222A may be formed on the basis of well-established recipes, wherein, in some illustrative embodiments, the respective etch process may also result in a substantially complete removal of the exposed portion of the etch stop layer 213.

In some illustrative aspects, the device 200 may be subject to an appropriately designed clean process to remove or reduce material residues or contaminants from the exposed surface of the metal region 212. For this purpose, well-established wet chemical recipes may be used.

FIG. 2c schematically illustrates the semiconductor device 200 in a further advanced manufacturing stage, in which the device 200 is exposed to a deposition ambient 240 designed such that a highly selective deposition of an alloy-forming species 241 at the bottom of the via 230A may be achieved. The alloy-forming species 241 may represent any appropriate material which may, in combination with the predominant material of the metal region 212, form an alloy having superior electromigration performance. For example, if copper may be used as the predominant material in the metal region 212, appropriate alloy-forming components may be, among others, tin, aluminum and the like. The alloy-forming species 241 may, due to the high selectivity of the deposition process 240, be provided above the critical area 231 in which a significantly increased resistance against electromigration may be desired, as previously explained. In one illustrative embodiment, the highly selective deposition process 240 may comprise an electrochemical deposition process, such as an electroless plating process. An electroless deposition process typically requires an active initiation of the chemical reaction of the agents contained in the corresponding plating solution in order to reduce and thus deposit the corresponding component or components, such as tin, to thereby form a uniform layer. Typically, the initiation of the chemical reaction may be accomplished by a catalytic material or on the basis of respective nucleation centers of small size in order to not unduly compromise the crystallinity of the material deposited. For example, materials such as platinum, palladium, copper, silver, cobalt and the like are known as highly efficient catalyst materials for activating the chemical reaction between a metal salt and a reducing agent contained in a corresponding electrolyte solution. Consequently, in many cases, the exposed surface of the metal region 212 may itself act as a catalyst, thereby initiating the desired deposition process. Hence, the alloy-forming species 241 may be provided with high reliability and uniformity with respect to cross-substrate variations and variations from substrate to substrate.

In other illustrative embodiments, the highly selective deposition process 240 may comprise highly directional techniques, such as physical vapor deposition on the basis of appropriately selected parameters, thereby accomplishing an increased deposition rate at horizontal portions, while maintaining the deposition rate on substantially vertical edges at a moderately low rate. Respective directional deposition techniques may, for instance, be used when the trench opening 222A is not yet formed at this manufacturing stage, while any non-desired material residues at sidewall portions of the via openings 230A may be removed by an isotropic etch process, which may leave sufficient material at the via bottom so as to provide the species 241 in a desired amount. The species 241 may be removed from other horizontal portions outside the via opening 230A during the further processing, depending on the process strategy.

FIG. 2d schematically illustrates the semiconductor device 200 when subjected to a treatment 250 for initiating an alloy-forming process, thereby diffusing the species 241 into the material of the metal region 212, which may be accomplished in a highly controlled manner so as to substantially restrict the resulting alloy, now referred to as alloy 241A, to the area 231, which may have similar lateral dimensions compared to the via opening 230A. The treatment 250 may comprise a heat treatment at elevated temperatures in the range of approximately 180-300° C. so as to obtain the desired diffusion activity substantially without degrading any other device components. During the heat treatment 250, the temperature and/or the duration may be appropriately controlled so as to obtain the desired lateral and vertical extension of the alloy 241A, thereby defining an appropriate contact area, which may also be referred to as contact or transition area 231, in which a via may be received in a later manufacturing stage.

As previously explained, the lateral dimension of the region 231 may be defined on the basis of the concentration of the alloy forming species 241. That is, areas of the metal region 212 having a concentration with respect to the species 241 that is above a predefined threshold may be considered as belonging to the contact region 231, while areas having a concentration below the threshold may be considered as being outside the area 231 thereby representing a “non-alloyed” portion of the metal region 212. In other cases, a maximum concentration of the species 241 may be used as a reference wherein a predefined threshold, i.e., percentage of the maximum concentration, may be used for distinguishing portions within the area 231 and outside the area 231. For example, in this sense, the lateral dimensions of the area 231 may be defined by a position at which the concentration of the species 241 has dropped to one tenth of the maximum concentration. In this sense, the lateral dimension of the area 231, in some illustrative embodiments, may be less than two times the lateral dimension of the via opening 230 at a bottom portion thereof. Consequently, the lateral extension of the area 231 may be significantly less compared to the length of the metal region 212, thereby substantially maintaining the global resistivity of the metal region 212, while nevertheless providing locally for a highly increased electromigration performance.

In one illustrative embodiment, the treatment 250 may be performed on the basis of process parameters which also enable an efficient out-gassing of gaseous components contained in the dielectric material 221 or any other exposed areas of the device 200, thereby providing superior conditions for a subsequent deposition of a barrier material. For instance, the process 250 may be performed in a sputter deposition chamber, which may be subsequently used for forming an appropriate barrier layer, such as a tantalum nitride layer, a tantalum layer and the like. In one embodiment, when starting at the manufacturing stage as shown in FIG. 2b, the metal region 212 may be efficiently exposed followed by an efficient cleaning process so as to remove contaminants from the exposed surface of the metal region 212, wherein the subsequent selective deposition 240 may provide an efficient cap layer for the further processing of the device 200. Thus, the process sequence may be made more robust in view of any queue times in the process flow prior to the deposition of a barrier material, since the alloy-forming species 241 may typically be less reactive compared to exposed sensitive metals, such as copper and the like.

FIG. 2e schematically illustrates the semiconductor device 200 during a process sequence 260 for forming a barrier layer 223 on exposed portions of the device 200. For instance, the process sequence 260 may comprise one or more deposition steps wherein, depending on the process strategy, intermediate re-sputter processes and the like may be performed to obtain the desired thickness and material composition of the layer 223. In other illustrative embodiments, the process sequence 260 may comprise, in addition to a sputter etch process, or alternatively thereto, other deposition techniques, such as CVD, self-limiting CVD techniques, which may also be referred to as atomic layer deposition (ALD), electroless deposition processes and the like. In one illustrative embodiment, as shown in FIG. 2e, the process sequence 260 may comprise an etch process such as a sputter etch process so as to remove a portion of the area 231, thereby forming a recess 232. Etching into the region 231 may be advantageous in view of overall process uniformity, process control and the like. That is, by etching into the material of the area 231 on the basis of a highly controllable etch process, any process variations of preceding patterning sequences for forming the via opening 230A may be reduced to a certain degree. Thus, the contact resistance between the first and the second metallization layers 210, 220 may be made more uniform, thereby also contributing to enhanced electrical performance and reliability. Moreover, since the area 231 including the alloy-forming species 241 may be provided in a highly localized manner, the corresponding vertical extension thereof may be selected to be greater compared to conventional strategies for enhancing the electromigration performance on the basis of the layer 112A, as previously explained with reference to FIG. 1b, since a significant extension in the vertical direction would unacceptably increase the overall resistivity of the metal line under consideration. According to the teaching disclosed herein, the recess 232 may be formed in a highly reliable and uniform manner, where, even for respective process variations, the recess 232 may be surrounded by material having the enhanced electromigration performance. Consequently, the recess 232 may be formed on the basis of less critical process parameters compared to conventional strategies.

FIG. 2f schematically illustrates the semiconductor device 200 in a further advanced manufacturing stage, in which the trench opening 222A and the via opening 230A are filled with a highly conductive metal, such as copper and the like, followed by an appropriate cap layer 225, which may be formed on the basis of similar criteria as previously explained with reference to the layer 213. That is, with respect to providing an appropriate cap layer for the metal line 222, conventional measures with respect to reducing the risk of void formation at a transition area to an overlying metallization layer may be omitted, since the same principles may be applied when forming a respective via connecting to the metal line 222.

Consequently, during operation of the semiconductor device 200, an electron flow, as indicated by arrow 226, may encounter the region 231 of increased electromigration resistance and hence the probability for creating a shallow void due to current-induced material flow may be significantly reduced, while the global electrical resistivity of the metal region 212 may not be unduly negatively affected.

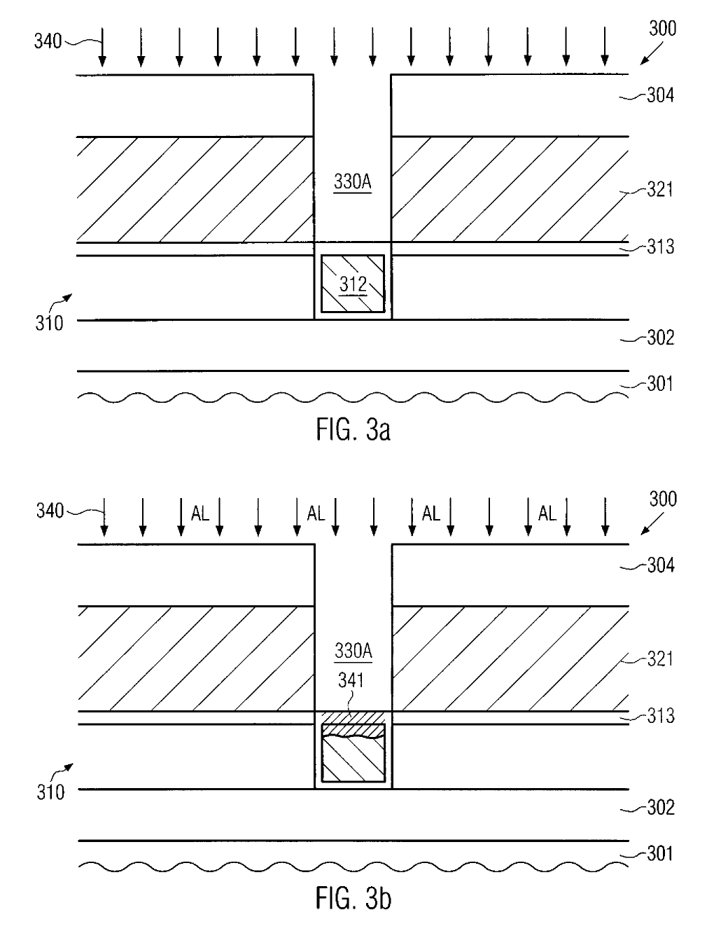

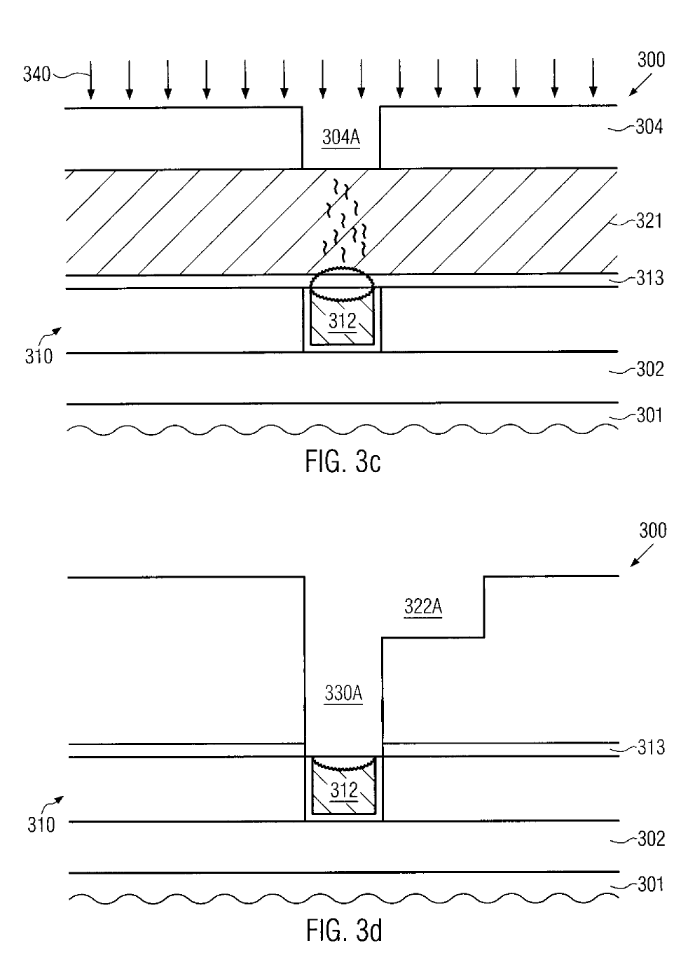

With reference to FIGS. 3a-3d, further illustrative embodiments will now be described in more detail, in which a highly directive particle bombardment may be used to incorporate an appropriate alloy-forming species into a metal region.

FIG. 3a schematically illustrates a semiconductor device 300 in a cross-sectional view which comprises a substrate 301, a device layer 302, a first metallization layer 310 and a dielectric material 321, which may represent the dielectric material for a via layer and an additional metallization layer, as previously explained, or which may represent the dielectric material of a via layer when a single damascene process technique is considered, as previously explained. The dielectric material 321 may comprise a via opening 330A, which may be located above a metal line 312 that extends in its length direction perpendicularly to the drawing plane of FIG. 3a. With respect to any components of the device 300 as described so far, the same criteria apply as previously explained with reference to the device 200. In the manufacturing stage shown in FIG. 3a, an etch stop layer 313 which may also act as an efficient cap layer for the metal line 312, as previously explained, may cover the material of the metal line 312, thereby substantially avoiding any undue reaction of the metal material with the environment. Furthermore, an etch mask 304, such as a resist mask, possibly in combination with an appropriate anti-reflective coating (ARC) material, may be formed above the dielectric material 321.

The semiconductor device 300 as shown in FIG. 3a may be formed on the basis of process techniques as previously described with reference to the devices 100 and 200. In particular, the etch mask 304 may be formed on the basis of well-established process techniques. After patterning the etch mask 304, well-established anisotropic etch recipes may be used to form the via opening 330A in the dielectric material 321, wherein the corresponding etch process may stop on or in the etch stop layer 313, as previously explained.

FIG. 3b schematically illustrates the semiconductor device 300 during a highly directional particle bombardment 340, which may comprise an ion implantation process in order to incorporate an appropriate alloy-forming species 341 in the metal line 312. For example, the ion implantation process 340 may be performed on the basis of aluminum, wherein process parameters such as implantation energy and dose may be selected so as to obtain a desired concentration and penetration depth of the species 341. Appropriate process parameters may readily be established on the basis of experiments, simulations and the like. Due to the highly directional nature of the process 340, a contamination of sidewalls of the via opening 330A may be maintained at a very low level, while also a respective penetration depth would be very small so that corresponding “contaminants” may be efficiently incorporated into a respective barrier material during the subsequent processing. After the incorporation of the species 341, the further processing may be continued, for instance by forming a trench opening, as previously described with reference to the device 200, thereby also exposing the metal line 312 within the via opening 330A, as previously described. Thereafter, an appropriate treatment may be performed to initiate the alloy-forming process, as previously described. In other cases, a via may be formed by removing the exposed portion of the etch stop layer 313 within the opening 330A, forming an alloy in the metal line 312 and filling the via opening 330A with a conductive barrier material and a highly conductive metal.

FIG. 3c schematically illustrates the semiconductor device 300 according to further illustrative embodiments, wherein the implantation process 340 is performed in an earlier manufacturing stage. That is, the etch mask 304 may be provided above the dielectric layer 321 and may comprise a respective opening 304A, which substantially corresponds to the via opening still to be formed in the material 321. Thus, the opening 304A may be considered as an alignment opening to align the species 341 incorporated by the implantation process 340 with respect to the metal region 312. Consequently, the process parameters, that is, the implantation energy of the process 340, may be selected appropriately based on simulation, experiment and the like so as to obtain a desired concentration of the species 341 within the metal region 312, wherein also a specified penetration depth may be selected on the basis of the implantation parameters. During the particle bombardment caused by the process 340, the structure of the material 321 within the area of the alignment opening 304A may be damaged, thereby providing an increased etch rate during the subsequent patterning of the dielectric material 321.

FIG. 3d schematically illustrates the semiconductor device 300 in a further advanced manufacturing stage, wherein the via opening 330A and a trench opening 322A may be formed in the dielectric material 321. This may be accomplished on the basis of process techniques as previously described, wherein the process sequence for patterning the via opening 330A may be performed on the basis of relaxed process constraints due to the increased etch rate, thereby resulting in an increased etch selectivity between the etch stop layer 313 and the material 321. Furthermore, during the corresponding anisotropic etch process, the essential amount of species 341, which may have been deposited within the material 321 during the preceding implantation process 340, may be removed since the species 341 may laterally be substantially restricted to an area corresponding to the alignment opening 304A. Thereafter, the further processing may be continued by initiating a diffusion and thus alloy-forming process, as previously described with reference to the device 200.

As a result, the subject matter disclosed herein provides semiconductor devices and corresponding manufacturing techniques in which the electromigration performance in the vicinity of via bottoms may be locally increased, substantially without affecting the total electrical resistivity of the metal line. Furthermore, the process may be performed as a self-aligned sequence, thereby ensuring high process reliability and robustness, while also providing a high degree of device uniformity. Moreover, the local formation of an appropriate alloy is compatible with advanced barrier techniques in which a recess is to be formed in the underlying metal region prior to depositing the barrier material, wherein the self-aligned techniques disclosed herein provide reliable “confinement” of the via end portion within the material area having the enhanced electromigration performance. The self-aligned process for forming the alloy may include an electroless deposition process and may be efficiently combined with conventional techniques, for instance by using a thermal treatment for out-gassing contaminants prior to the deposition of a barrier material as a process for initiating the alloy-forming process.

The particular embodiments disclosed above are illustrative only, as the invention may be modified and practiced in different but equivalent manners apparent to those skilled in the art having the benefit of the teachings herein. For example, the process steps set forth above may be performed in a different order. Furthermore, no limitations are intended to the details of construction or design herein shown, other than as described in the claims below. It is therefore evident that the particular embodiments disclosed above may be altered or modified and all such variations are considered within the scope and spirit of the invention. Accordingly, the protection sought herein is as set forth in the claims below.

What is claimed:

1. A method, comprising:
forming an opening in a dielectric layer formed above a metal-containing region of a metallization structure of a semiconductor device;
applying an alloy-forming species through said opening so as to bring said alloy-forming species in contact with material of said metal-containing region;
locally forming an alloy in said metal-containing region connecting to said opening; and
filling said opening with a metal-containing material.

2. The method of claim 1, further comprising forming a barrier layer after introducing said alloy-forming species and prior to filling said opening with the metal-containing material.

3. The method of claim 1, wherein introducing said alloy-forming species comprises exposing a portion of said metal-containing region and performing a selective electrochemical deposition process.

4. The method of claim 1, wherein introducing said alloy-forming species comprises performing an implantation process.

5. The method of claim 4, wherein forming said opening comprises etching said dielectric layer on the basis of an etch mask and wherein said etch mask is used as a mask for said implantation process.

6. The method of claim 1, wherein locally forming said alloy comprises performing a heat treatment.

7. The method of claim 1, further comprising forming a trench connecting to said opening and filling said opening and said trench in a common process.

8. The method of claim 7, wherein said trench is formed prior to applying said alloy-forming species.

9. The method of claim 2, further comprising forming a recess in said alloy prior to forming said barrier layer.

10. A method of forming an interconnect structure of a semiconductor device, the method comprising:
providing an alignment opening in a layer stack formed above a metal line, said alignment opening to be used for forming a via connecting to said metal line; and
locally forming an alloy in a portion of said metal line using said alignment opening to align said portion to said via.

11. The method of claim 10, wherein said alignment opening represents an opening in an etch mask formed above a dielectric layer that is located above said metal line.

12. The method of claim 11, wherein locally forming said alloy comprises performing an implantation process to incorporate an alloy-forming species in said portion.

13. The method of claim 12, further comprising forming a via opening in said dielectric layer after performing said implantation process.

14. The method of claim 12, further comprising forming a via opening in said dielectric layer prior to performing said implantation process.

15. The method of claim 10, wherein said alignment opening represents a via opening formed in said dielectric layer, said via opening exposing material of said metal line.

16. The method of claim 15, wherein locally forming said alloy comprises selectively forming an alloy-forming species on said exposed material of the metal line.

17. The method of claim 16, wherein selectively forming said alloy-forming species comprises performing an electrochemical deposition process.

18. A semiconductor device, comprising:
a first metallization layer comprising a first metal region, said first metal region comprising an alloy that is laterally substantially restricted to a contact region;
a second metallization layer formed above said first metallization layer and comprising a second metal region; and
an interconnect structure connecting said first and second metal regions, one end portion of said interconnect structure terminating in said contact region.

19. The semiconductor device of claim 18, wherein a lateral extension of said contact region is less than twice a lateral dimension of said end portion of said interconnect structure.

20. The semiconductor device of claim 19, wherein said interconnect structure comprises at least on sidewalls thereof a conductive barrier layer.
